(19) United States
(12) Patent Application Publication
(10) Pub. No.: US 2008/0099781 A1
(43) Pub. Date: May 1, 2008

(54) Method of manufacturing III group nitride semiconductor thin film and method of manufacturing III group nitride semiconductor device using the same

(75) Inventors: Rak Jun Choi, Suwon (KR); Kureshov Vladimir, Suwon (KR); Bang Won Oh, Sungnam (KR); Gil Han Park, Sungnam (KR); Hee Seok Park, Suwon (KR); Seong Eun Park, Suwon (KR); Young Min Park, Suwon (KR); Min Ho Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/898,955

(22) Filed: Sep. 18, 2007

(30) Foreign Application Priority Data
Oct. 31, 2006 (KR) 10-2006-106792

(51) Int. Cl. H01L 33/00; H01L 21/20

(52) U.S. Cl. 257/103; 438/494; 257/E21.108; 257/E33.023

(57) ABSTRACT

A method of manufacturing a III group nitride semiconductor thin film and a method of manufacturing a nitride semiconductor light emitting device employing the III group nitride semiconductor thin film manufacturing method, the III group nitride semiconductor thin film manufacturing method including: growing a first nitride single crystal on a substrate for growing a nitride; applying an etching gas to a top surface of the first nitride single crystal to selectively form a plurality of pits in a high dislocation density area; and growing a second nitride single crystal on the first nitride single crystal to maintain the pits to be void.

### CROSS-REFERENCE TO RELATED APPLICATIONS

This application claims the priority of Korean Patent Application No. 2006-0106792 filed on Oct. 31, 2006, in the Korean Intellectual Property Office, the disclosure of which is incorporated herein by reference.

### BACKGROUND OF THE INVENTION

1. Field of the Invention

The present invention relates to a method of manufacturing a III group nitride semiconductor thin film, and more particularly, to a method of more simply growing a nitride semiconductor thin film by employing a lateral growth mode and a method of manufacturing a nitride semiconductor device using the method.

2. Description of the Related Art

In general, since III group nitride semiconductors are capable of emitting light of a wide region not only overall visible light region but also an ultraviolet region, III group nitride semiconductors are generally used as a material for manufacturing visible light and ultraviolet light emitting devices in the form of ones of LEDs and laser diodes (LDs) and a bluish green light device.

To manufacture light devices including nitride semiconductors, it is required a technology for growing a III group nitride semiconductor into a high quality single crystal thin film. However, since it is difficult to provide a substrate suitable for a lattice constant and a thermal expansion coefficient of III group nitride semiconductors, there is a great limitation on a method of growing a single crystal thin film.

As general methods of growing a III group nitride semiconductor, there is a method of growing on a sapphire substrate, which is a heterogeneous substrate, by heteroepitaxy using metal-organic chemical vapor deposition (MOCVD) and molecular beam epitaxy (MBE). However, though using the sapphire substrate, due to inconsistencies in the lattice constant and thermal expansion coefficient, it is difficult to directly grow a high quality III group nitride semiconductor single crystal. Accordingly, it is general to employ a two-step growing method including a low-temperature nucleation layer and a high-temperature single crystal growth. Though a low-temperature nucleation layer is formed on a sapphire substrate and a III group nitride semiconductor single crystal is grown thereon by using the two-step growing method, there exist crystal defects from about 10⁹ to about 10¹⁰ cm⁻².

Recently, to reduce crystal defects of III group nitride semiconductors, lateral epitaxial overgrowth (LEO) shown in FIGS. 1A through 1D is used.

Referring to FIG. 1A, a GaN nitride layer 12 is grown on a sapphire substrate 11. Referring to FIG. 1B, a dielectric mask 13 having a stripe pattern is formed on the GaN intride layer 12. A nitride single crystal growth process is performed using LEO on the GaN nitride 12 on which the dielectric mask 13 is formed. When a height of a GaN nitride single crystal 14′ is greater than a height of the dielectric mask 13, the GaN nitride single crystal 14′ is laterally grown on the dielectric mask 13 as shown in FIG. 1C, and finally, coalesced to form a nitride single crystal layer 14 on the dielectric mask 13 as shown in FIG. 1D.

In the described LEO process, it is required that the GaN nitride layer 12 and a dielectric layer for a mask are grown in a chamber for performing one of the MOCVD and MBE process, are taken out from the chamber to perform one of photoresist and etching processes for forming a pattern, and are disposed again in the chamber to perform a process of growing a nitride.

As described above, the nitride semiconductor thin film manufacturing process using the general LEO process is incapable of providing a sequential nitride growing process according to mask forming. Therefore, there is required a large amount of manufacturing time and there exists complexity in-process.

### SUMMARY OF THE INVENTION

An aspect of the present invention provides a method of manufacturing a nitride semiconductor thin film, the method capable of providing a consecutive nitride growth process by effectively preventing propagation of a dislocation to improve crystallizability in a chamber for growing a nitride in a lateral growth mode.

An aspect of the present invention also provides a method of manufacturing a nitride semiconductor device using the method of manufacturing a nitride semiconductor thin film.

According to an aspect of the present invention, there is provided a method of manufacturing a III group nitride semiconductor thin film, the method including: growing a first nitride single crystal on a substrate for growing a nitride; applying an etching gas to a top surface of the first nitride single crystal to selectively form a plurality of pits in a high dislocation density area; and growing a second nitride single crystal on the first nitride single crystal to maintain the pits to be void.

The first nitride single crystal may have a thickness of about 0.5 to 1.5 μm.

The pit may have a nonpolar crystal face.

To prevent growing a nitride in the pit and to embody a desired lateral growth theory, the pit may have a width of 1.5 or less.

A desired pit structure may be formed on a surface of the first nitride single crystal by applying an etching gas into a reaction chamber for growing a nitride. The etching gas may include one gas selected from a group consisting of H₂, N₂, Ar, HCl, HBr, SiCl₄, and a mixed gas thereof. The applying an etching gas may be performed at a temperature of 500 to 1200.

To obtain more excellent surface morphology, the growing a second nitride single crystal may include: growing an intermediate layer comprising two or more multilayers comprising a first layer formed of a metal and a second layer formed of nitrogen; and growing the second nitride single crystal on the intermediate layer. In this case, the intermediate layer may be formed of Ga/N/GaN. On the other hand, the intermediate layer may be formed of Al/In/Ga/N.

After the growing the second nitride single crystal, applying an etching gas to a top surface of the second nitride single crystal to form a plurality of pits; and forming an additional nitride semiconductor layer on the second nitride semiconductor layer to maintain the plurality of pits may be repeated one or more times, thereby obtaining a nitride semiconductor thin film having a high quality.

The III group nitride semiconductor thin film manufactured by the method according to an embodiment of the present invention may be effectively employed as a layer of a nitride semiconductor light emitting diode.

According to another aspect of the present invention, there is provided a method of manufacturing III group nitride semiconductor device, the method including: growing a first nitride single crystal on a substrate for growing a nitride; applying an etching gas to a top surface of the first nitride single crystal to selectively form a plurality of pits in a high dislocation density area; growing a second nitride single crystal on the first nitride single crystal to maintain the pits to be void; and sequentially growing a first conductivity type nitride layer, an active layer, and as second conductivity type nitride layer on the second nitride single crystal.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1D are cross-sectional views for each process, illustrating a method of manufacturing a nitride semiconductor thin film using a general lateral epitaxial overgrowth (LEO);

FIGS. 2A through 2C are cross-sectional views for each process, illustrating a method of manufacturing a nitride semiconductor thin film, according to an embodiment of the present invention;

FIG. 3 is a schematic diagram illustrating a theory of a lateral growth of a nitride semiconductor thin film employed in an exemplary embodiment of the present invention;

FIGS. 4A through 4D are cross-sectional views for each process, illustrating a method of manufacturing a nitride semiconductor thin film, according to another embodiment of the present invention;

FIGS. 5A and 5B are timing charts of a pulse atomic layer epitaxy method to illustrate examples of a nitride layer growth method capable of being particularly employed in the nitride semiconductor thin film manufacturing methods according to the embodiments of the present invention, respectively; and

FIG. 6 is a side cross-sectional view illustrating a nitride semiconductor light emitting device employing a nitride semiconductor thin film manufactured by the method according to an exemplary embodiment of the present invention.

### DETAILED DESCRIPTION OF THE PREFERRED EMBODIMENT

Exemplary embodiments of the present invention will now be described in detail with reference to the accompanying drawings.

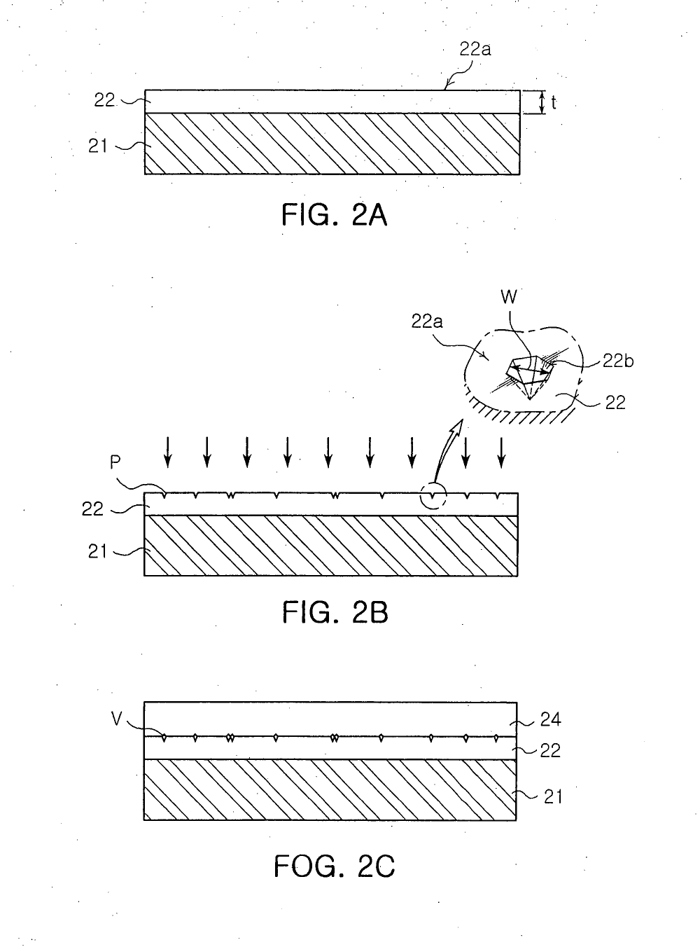

FIGS. 2A through 2C are cross-sectional views for each process, illustrating a method of manufacturing a III group nitride semiconductor thin film, according to an embodiment of the present invention.

Referring to FIG. 2A, the method of manufacturing a III group nitride semiconductor thin film starts with growing a first nitride single crystal 22 on a substrate 21 for growing a nitride.

The substrate 21 may be, but not limited to, a sapphire substrate and may be one of a heterogeneous substrate and a homogeneous substrate identical to a GaN substrate, which comprises a material selected from a group consisting of SiC, Si, MgAl₂O₄, MgO, LiAlO₂, and LiGaO₂.

The first nitride single crystal 22 may be grown to a certain thickness via known processes such as metal organic chemical vapor deposition (MOCVD), molecular beam epitaxy (MBE), and hydride vapor phase epitaxy (HVPE), and particularly, may be grown to a thickness where a defect density of a nitride single crystal is rapidly increased. Considering this, a thickness t of the first nitride single crystal 22 may be from about 0.5 to about 1.5.

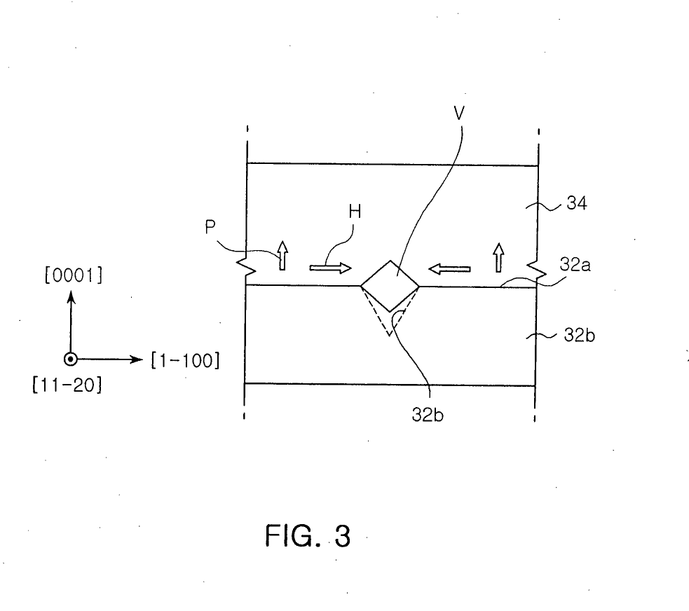

In detail, the sapphire substrate may have a top surface that is a crystal face in a c-axis direction. The first nitride single crystal 22 may have a top surface 22a that is a face in a [0001]-axis, which will be described in detail with reference to FIG. 3.

Referring to FIG. 2b, an etching gas is applied to the top surface 22a of the first nitride single crystal 22, thereby forming a plurality of pits P.

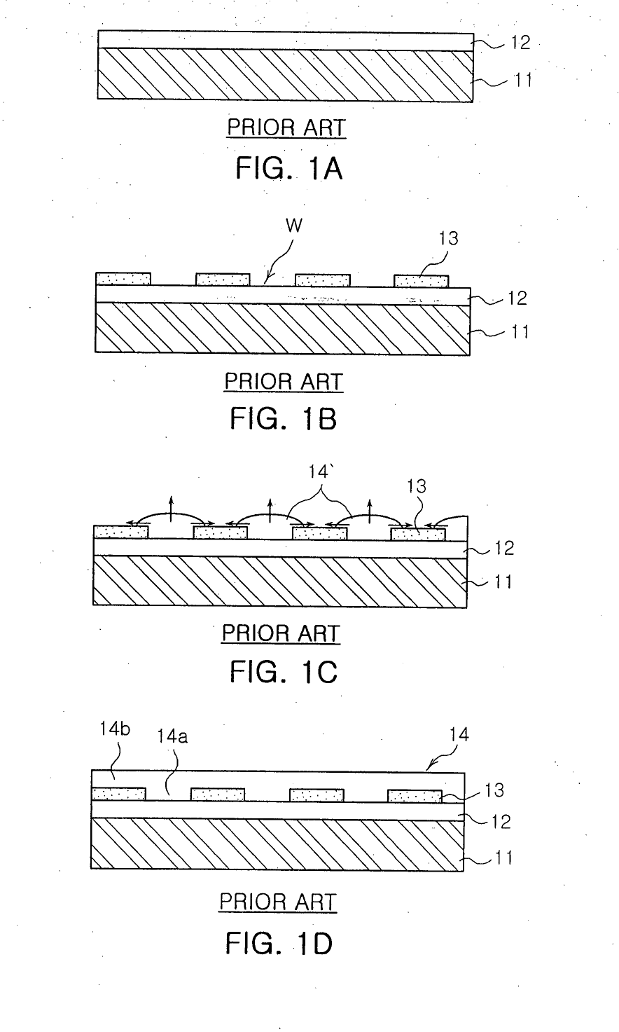

The present etching process may be performed in-situ of a chamber where nitride growth is performed. Also, the plurality of pits P formed by the etching process may be employed as means for a lateral growth mode. Accordingly, different from the general process shown in FIG. 1, a consequent process may be performed.

An etching gas capable of being employed to the present embodiment may be, but not limited to, a gas selected from a group consisting of H₂, N₂, Ar, HCl, HBr, SiCl₄, and a mixed gas thereof. To improve an etching effect, the present etching process may be performed at a temperature of 500 to 1200. Also, when performing the etching process, a pressure condition in a chamber may be 30 to 1000 mbar.

The plurality of pits P may be selectively formed in a high dislocation density area and may be a little irregularly arranged. The pit P formed on the first nitride single crystal 22 has a hexagonal pyramid structure as shown in an enlarged portion of FIG. 2B. As described above, when the top surface 22a of the first nitride single crystal 22 is in the [0001]-axis, an inclined plane 22b of the pit P becomes a nonpolar crystal face such as a stable S-plane.

The pit P in the shape of the hexagonal pyramid may be formed to have a width W of approximately 1.5 or less to prevent a growth of a nitride therein and to embody a desired lateral growth mode while performing a following growth process. Since depending on the width W, a depth of the pit P may be approximately 2 or less.

Referring to FIG. 2c, to maintain the pit P to be a void V, a second nitride single crystal 24 is grown on the first nitride single crystal 22.

This will be described in detail with reference to FIG. 3. FIG. 3 is a schematic diagram illustrating a lateral growth theory of a nitride semiconductor thin film employed in a present embodiment. As the exemplary embodiment of the present invention described with reference to FIGS. 2A to 2B, the sapphire substrate may have the crystal face in the c-axis direction as the top surface, and a top surface 32a of a first nitride single crystal 32 may be a [0001]-crystal face. In this case, an inclined plane 32b of a pit is {1-101}-plane that is an S-plane, which is much stable.

Accordingly, since there hardly are be occurred a growth on the inclined plane 32b of the pit, the plane 32b that is a stable S-plane, a nitride single crystal layer 34 is generally regrown on a top surface except for the pit. Also, a perpendicular growth P in a c<0001>-axis direction, which is relatively quick, is performed simultaneously with a horizontal growth H in an m<1-100>-axis and an a <11-20>-axis. As a result, the regrown nitride single crystal 34 is coalesced with the pit by the horizontal growth H and a dislocation progress direction in the lateral growth process is prevented or moved to a portion to be coalesced, thereby improving crystallizability.

On the other hand, though a pit area is coalesced with the regrown nitride single crystal 34, as described above, the inclined plane 32b is stable. Accordingly, though the pit is deformed by a little deposition due to a downward transfer of a material, the pit is void V when a regrowth is completed.

In the method of manufacturing the III group nitride semiconductor thin film, an etching process and a regrowth process in-situ may be repeated to grow a nitride single crystal having a higher quality of crystallizability.

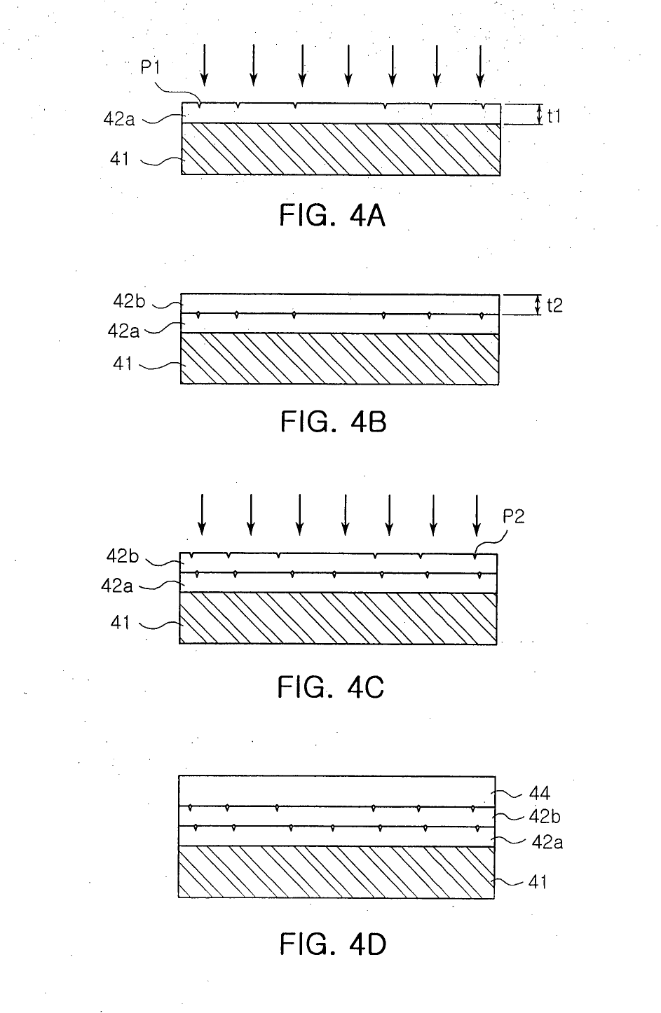

FIGS. 4A through 4D are cross-sectional views illustrating respective processes of a method of manufacturing a nitride semiconductor thin film according to another embodiment of the present invention.

Referring to FIG. 4A, a first nitride single crystal 42a is grown on a substrate 41 for growing a nitride, an etching gas is applied to a top surface of the first nitride single crystal 42a, thereby forming a plurality of pits P1.

The substrate 41 may be, but not limited to, a sapphire substrate and may be one of a heterogeneous substrate and a homogeneous substrate, as shown in FIG. 2A. A thickness t1 of the first nitride single crystal 42a may be from about 0.5 to about 1.5, where a defect density in a nitride single crystal is increased.

An etching gas capable of being employed to the present embodiment may be, but not limited to, a gas selected from a group consisting of H₂, N₂, Ar, HCl, HBr, SiCl₄, and a mixed gas thereof. To improve an etching effect, the present etching process may be performed at a temperature of 500 to 1200. To embody a desired lateral growth mode, the pit may have a width of 1.5 or less and have an inclined plane of a stable S-plane.

Referring to FIG. 4B, to maintain the pit P1 to be void, a second nitride single crystal 42b is regrown above the first nitride single crystal 42a.

In a process of regrowing the second nitride single crystal 42b, as described with reference to FIG. 3, a crystal layer where a dislocation density is greatly decreased due to a lateral growth mode may be grown. However, since a predetermined dislocation still exists, the growth stops at an appropriate thickness.

Generally, since the second nitride single crystal 42b has a more improved crystallizability than that of the first nitride single crystal 42a, a desired thickness has a larger range than that of the thickness t1 of the first nitride single crystal 42a.

Referring to FIG. 4C, a process of applying an etching gas to the second nitride single crystal 42b is performed again. The etching process may be performed in a condition similar to that described with reference to FIG. 4A. The described etching gas is injected into a chamber for growing a nitride and applied to a surface of the second nitride single crystal 42b, thereby generating a pit in the shape of a hexagonal pyramid, in an area where a dislocation density is concentrated.

Referring to FIG. 4D, a third nitride single crystal is regrown on a top surface of the second nitride single crystal 42b with a plurality of pits formed thereon. The third nitride single crystal regrown here may be obtained by a method similar to the method of regrowing the nitride single crystal parallel with the lateral growth mode described with reference to FIG. 4B and may have more excellent crystallizability.

As described above, a process of regrowing a nitride single crystal, in which an etching process of forming the plurality of pits and the lateral growth mode are combined with each other in-situ is repeated desired times, thereby greatly improving crystallizability.

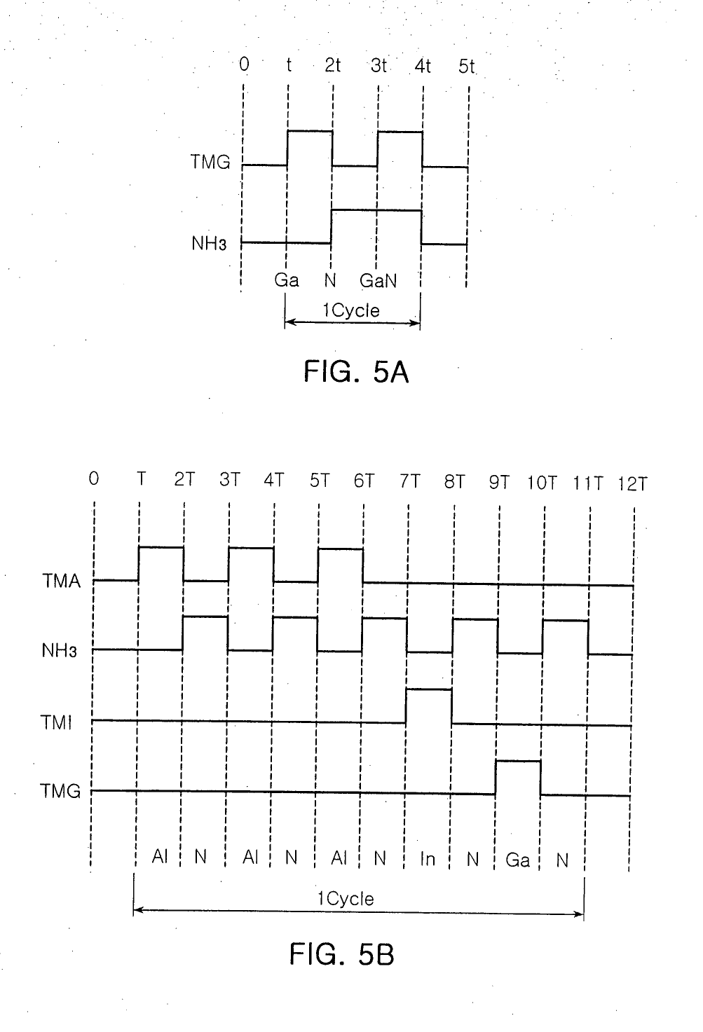

In addition, the process of regrowing a nitride single crystal in the present embodiment may embody a quick coalescence required in the present invention and may greatly improve surface morphology. FIGS. 5A and 5B are timing charts illustrating a nitride single crystal growth process.

Referring to FIG. 5A, one cycle includes four clocks. In detail, only TriMethylGalium (TMG) is injected in a first clock (t to 2t), only NH₃ is injected in a second clock (2t to 3t), and TMG and NH₃ are injected together in a third clock (3t to 4t). In other words, Ga is grown on a GaN layer, N is grown thereon, and GaN is grown thereon. That is, Ga/N/GaN layer may be formed in the one cycle. Forming the Ga/N/GaN multi layer by the one cycle may be performed many times. For example, 2 to 100 cycles may be performed. Particularly, when performing 10 to 20 cycles, a GaN layer having morphology with a high quality may be obtained.

On the other hand, referring to FIG. 5B, one cycle may be formed as follows. In detail, only TriMethyl Aluminum (TMA) is injected in a first clock (T to 2T), only NH₃ is injected in a second clock (2T to 3T). Similarly, TMA, NH₃, TMA, and NH₃ are sequentially injected in a third clock (3T to 4T), a fourth clock (4T to 5T), a fifth clock (5T to 6T), a sixth clock (6T to 7T). Subsequently, only TriMethylIndium (TMI) is injected in a seventh clock (7T to 8T), only NH₃ is injected in an eighth clock (8T to 9T), only TMG is injected in a ninth clock (9T to 10T), and only NH₃ is injected in a tenth clock (10T to 11T). According to the one cycle, AlN/InN/GaN layer is formed on a low temperature GaN layer 220, which is performed many times, thereby obtaining a nitride layer having morphology with a high quality.

The nitride single crystal growth process described above is applied to a nitride layer with a pit structure formed thereon, as a second growth process, thereby not only expecting a quick coalescence due to a lateral growth but also greatly improving surface morphology.

The nitride single growth method according to the present embodiment may be effectively employed by a method of manufacturing a light emitting diode with excellent reliability.

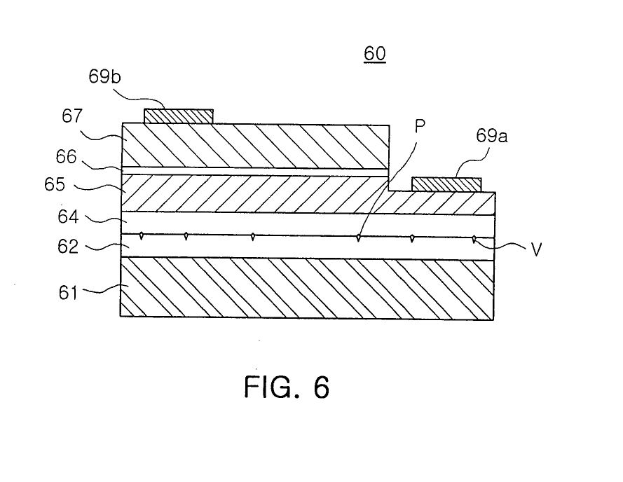

FIG. 6 is a side cross-sectional view illustrating a nitride semiconductor light emitting device 60 employing a nitride semiconductor thin film manufactured by the method according to an exemplary embodiment of the present invention.

Referring to FIG. 6, the nitride semiconductor light emitting device 60 includes a first nitride single crystal 62 and second nitride single crystal 64 formed on a substrate 64 and a first conductivity type nitride semiconductor layer 65, active layer 66, and second conductivity type nitride semiconductor layer 67 sequentially formed thereon. Also, first and second electrodes 69a and 69b are provided on the first and second conductivity type nitride semiconductor layers 65 and 67, respectively.

A process of growing the first nitride single crystal 62 and second nitride single crystal 64 having a plurality of voids V therebetween may be considered to be formed by the nitride single crystal growth process described with reference to FIGS. 2A through 2C.

That is, the first nitride single crystal 62 is grown by a first growth process, and a plurality of pits is provided by applying an etching gas in-situ. The second nitride single crystal 64 is formed in a growth mode combined with a lateral growth, using the plurality of pits, thereby obtaining the second nitride single crystal 64 having excellent crystallizability. Accordingly, crystallizability of the first and second conductivity type nitride semiconductor layers 65 and 67 and active layer 66 formed thereon is greatly improved. Therefore, the nitride semiconductor light emitting device 60 may be more reliable.

In the embodiment described with reference to FIG. 6, the second nitride single crystal 64 and the first conductivity type nitride semiconductor layer 65 are sequentially formed via separate processes. However, it may be considered that the second nitride single crystal 64 itself is doped with a first conductivity type impurity to form a first conductivity type nitride semicondutor layer.

Also, as in the present embodiment, the nitride single crystal growth process according to the present invention may be employed as an additional cystallizability structure on a substrate to be used to improve a growth condition of a first conductivity type nitride semiconductor layer. Also, the nitride single crystal growth process may be used as a process of forming the layers by being employed in the middle of the first conductivity type nitride semiconductor layer or the second conductivity type nitride semiconductor layer disposed thereabove.

As described above, according to the present invention, a process of inducing a lateral growth mode for improving crystallizability is embodied in a chamber for forming a pit structure using an etching gas and growing a nitride via a regrowth process, thereby providing consequent nitride growth process and manufacturing a nitride semiconductor thin film having crystallizability with a high quality. Also, it is expected that a nitride semiconductor light emitting device with excellent reliability may be provided by applying the nitride semiconductor thin film manufacturing method to a light emitting device manufacturing method.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a III group nitride semiconductor thin film, the method comprising:
growing a first nitride single crystal on a substrate for growing a nitride;
applying an etching gas to a top surface of the first nitride single crystal to selectively form a plurality of pits in a high dislocation density area; and
growing a second nitride single crystal on the first nitride single crystal to maintain the pits to be void.

2. The method of claim 1, wherein the first nitride single crystal has a thickness of about 0.5 to 1.5.

3. The method of claim 1, wherein the pit has a nonpolar crystal face.

4. The method of claim 1, wherein the pit has a width of 1.5 or less.

5. The method of claim 1, wherein the etching gas comprises one gas selected from a group consisting of H₂, N₂, Ar, HCl, HBr, SiCl₄, and a mixed gas thereof.

6. The method of claim 1, wherein the applying an etching gas is performed at a temperature of 500 to 1200.

7. The method of claim 1, wherein the growing a second nitride single crystal comprises:
growing an intermediate layer comprising two or more multilayers comprising a first layer formed of a metal and a second layer formed of nitrogen; and
growing the second nitride single crystal on the intermediate layer.

8. The method of claim 7, wherein the intermediate layer is formed of Ga/N/GaN.

9. The method of claim 7, wherein the intermediate layer is formed of Al/In/Ga/N.

10. The method of claim 1, further comprising:
applying an etching gas to a top surface of the second nitride single crystal to form a plurality of pits; and
forming an additional nitride semiconductor layer on the second nitride semiconductor layer to maintain the plurality of pits,
wherein the two operations are performed after the growing the second nitride single crystal and repeated one or more times.

11. A nitride semiconductor light emitting diode comprising a III group nitride semiconductor thin film manufactured by the method of claim 1.

12. A method of manufacturing III group nitride semiconductor device, the method comprising:
growing a first nitride single crystal on a substrate for growing a nitride;
applying an etching gas to a top surface of the first nitride single crystal to selectively form a plurality of pits in a high dislocation density area;
growing a second nitride single crystal on the first nitride single crystal to maintain the pits to be void; and
sequentially growing a first conductivity type nitride layer, an active layer, and as second conductivity type nitride layer on the second nitride single crystal.
